(19) United States
(12) Patent Application Publication
(10) Pub. No.: US 2014/0346592 A1
(43) Pub. Date: Nov. 27, 2014

(54) SEMICONDUCTOR DEVICE

(71) Applicants: Akitaka Soeno, Toyota-shi (JP); Toshimasa Yamamoto, Ichinomiya-shi (JP); Yukihiko Watanabe, Nagoya-shi (JP)

(72) Inventors: Akitaka Soeno, Toyota-shi (JP); Toshimasa Yamamoto, Ichinomiya-shi (JP); Yukihiko Watanabe, Nagoya-shi (JP)

(73) Assignees: DENSO CORPORATION, Kariya-shi (JP); TOYOTA JIDOSHA KABUSHIKI KAISHA, Toyota-shi (JP)

(21) Appl. No.: 14/363,523

(22) PCT Filed: Dec. 6, 2012
(86) PCT No.: PCT/JP2012/007831

§ 371 Date: Jun. 6, 2014

(30) Foreign Application Priority Data
Dec. 9, 2011 (JP) 2011-270084

(51) Int. Cl. H01L 29/78; H01L 29/423; H01L 29/10; H01L 29/51

(52) U.S. Cl. CPC H01L 29/7813; H01L 29/512; H01L 29/42368; H01L 29/1095
USPC 257/333

(57) ABSTRACT

A vertical MOSFET includes: a semiconductor substrate comprising a drain layer, a drift layer, a body layer, and a source layer; and a trench gate penetrating through the source layer and the body layer from an upper surface of the semiconductor substrate and reaching the drift layer. The trench gate includes a gate electrode; a first insulating film disposed on a bottom surface of a trench formed in the semiconductor substrate; a second insulating film disposed at least on a side surface of the trench, and in contact with the body layer; and a third insulating film disposed between the gate electrode and the second insulating film, and formed of a material of which dielectric constant is higher than a dielectric constant of the second insulating film.

### TECHNICAL FIELD

### Cross-Reference to Related Application

This application claims priority to Japanese Patent Application No. 2011-270084 filed on Dec. 9, 2011, the contents of which are hereby incorporated by reference into the present application.

The teaching herein relates a semiconductor device provided with a vertical MOSFET having a trench gate.

### BACKGROUND ART

In Japanese Patent Application Publication No. 2005-223255, in order to raise a maximum voltage of a trench gate-type semiconductor device, a thick insulating film is formed on a bottom surface of a trench. Leakage current is suppressed by this thick insulating film, and the maximum voltage of the semiconductor device is raised.

### SUMMARY OF INVENTION

In Japanese Patent Application Publication No. 2005-223255, a corner portion of a lower end of a gate electrode and a semiconductor substrate are separated by a comparatively thin insulating film that also serves as an insulating film on a trench surface side. In order to prevent dielectric breakdown at the corner portion of the lower end of the gate electrode, increasing a thickness of this portion of the insulating film is suggested. However, if the insulating film at the corner portion of the lower end of the gate electrode is made thick, the insulating film of the trench side surface also becomes thick, whereby channel formation when the gate electrode is turned on is impeded, resulting in high turn-on resistance of the semiconductor device.

A vertical MOSFET disclosed in the present specification comprises: a semiconductor substrate comprising a first conductivity type drain layer, a first conductivity type drift layer formed on an upper surface of the drain layer, a second conductivity type body layer formed on an upper surface of the drift layer, and a first conductivity type source layer formed on a part of an upper surface of the body layer; and a trench gate penetrating through the source layer and the body layer from an upper surface of the semiconductor substrate and reaching the drift layer. The trench gate comprises a gate electrode; a first insulating film; a second insulating film; and a third insulating film. The first insulating film is disposed on a bottom surface of a trench formed in the semiconductor substrate. The second insulating film is disposed at least on a side surface of the trench, and is in contact with the body layer. The third insulating film is disposed between the gate electrode and the second insulating film, and is formed of a material of which dielectric constant is higher than a dielectric constant of the second insulating film.

In the above-described MOSFET, the second insulating film and the third insulating film are provided between the corner portion of the lower end of the gate electrode and the semiconductor substrate. The third insulating film is formed of a material with a higher dielectric constant than that of the second insulating film, and so even when the film thickness is increased to secure a high maximum voltage, an increase in the turn-on voltage can be suppressed. Further, if the third insulating film with a high dielectric constant is in contact with the semiconductor substrate, many carriers are captured at an interface state at the interface between the third insulating film and the semiconductor substrate, and the speed of channel formation may become slow. In the above-described MOSFET, the second insulating film with a comparatively low dielectric constant is in contact with the body layer, so that slowing of the speed of channel formation can also be prevented. Through the above-described configuration, a MOSFET with a high maximum voltage and with excellent turn-on characteristics can he provided.

### BRIEF DESCRIPTION OF DRAWINGS

FIG. 1 shows a cross-sectional view of a MOSFET of Embodiment 1.

FIG. 2 shows a relation between a film thickness of a second insulating film and a film thickness of a third insulating film in the MOSFET of Embodiment 1.

### DESCRIPTION OF EMBODIMENTS

In a MOSFET disclosed in the present specification, a first insulating film is provided on a bottom surface of a trench formed in a semiconductor substrate. It is preferable that the film thickness of the first insulating film be greater than the film thickness of a second insulating film and the film thickness of a third insulating film. Here, the film thickness of the first insulating film is the thickness in the depth direction of the semiconductor substrate. The second insulating film may be provided only on side surfaces of the trench, or may be provided on the side surfaces of the trench and on the surface of the first insulating film. Here, a trench side surface is a portion not covered by the first insulating film among the inner wall of the trench. The second insulating film is in contact with a body layer and with the third insulating film. Further, the second insulating film may for example be in contact with the first insulating film, a drift layer, a source layer. It is preferable that a lower end of the second insulating film extends to be in contact with a surface of the first insulating film. The third insulating film is provided between a gate electrode and the second insulating film. The third insulating film is in contact with the gate electrode and the second insulating film.

The third insulating film is formed of material with a higher dielectric constant than the second insulating film. No limitations in particular are imposed on the material of the second insulating film, but it is preferable that silicon oxide (SiO₂) be used. In this case, the material of the third insulating film is a film with a dielectric constant higher than that of silicon oxide, and while no limitations in particular are imposed, examples include Si₃N₄ or another silicon nitride (SiNₓ), or aluminum oxide (Al₂O₃), tantalum oxide (Ta₂O₅), lanthanum oxide (La₂O₃), or another metal oxide with a dielectric constant higher than that of silicon oxide. Table 1 shows the dielectric constants of the materials given here as examples.

TABLE 1

| Material | Dielectric constant |
|---|---|
| SiO₂ | 3.9 |
| Si₃N₄ | up to 7 |
| Al₂O₃ | 8.5 to 10 |
| Ta₂O₅ | up to 25 |
| La₂O₃ | 27 |

In the above-described MOSFET, the material of the second insulating film may be silicon oxide, and the dielectric constant of the material of the third insulating film may be higher than the dielectric constant of silicon oxide.

It is preferable that the MOSFET disclosed in the present specification satisfies the following formulas (11) and (12). Here, k2 is the dielectric constant of the second insulating film, X is the film thickness of the second insulating film, k3 is the dielectric constant of the third insulating film, and Y is the film thickness of the third insulating film.

[Math. 1]

X+Y>T_{OX}/\sqrt{2} (11)

(k3/k2)(X−T)+Y<0 (12)

In formula (11), Tox is the minimum value of the film thickness of the insulating film necessary to secure reliability with respect to time-dependent dielectric breakdown (TDDB). By setting the values of X and Y within the range in which formula (11) is satisfied, a MOSFET with an excellent time-dependent dielectric breakdown characteristic can be obtained. It is preferable that Tox be 50 nm or greater, and still more preferable that Tox be 100 nm or greater. When the material of the semiconductor substrate is silicon (Si), Tox can be made approximately 100 nm. When the material of the semiconductor substrate is silicon carbide (SiC), by making the state density at the interface between the trench gate and the substrate from 10¹¹ to 10¹²/cm², Tox can be made approximately 100 nm.

In formula (12), T is the maximum value of the film thickness of the insulating film for satisfactory channel formation when the MOSFET is turned on, in a case where only the second insulating film is formed. By setting the values of X and Y within the range in which formula (12) is satisfied, a MOSFET with an excellent turn-on characteristic can be obtained. The value of T is set according to the material of the semiconductor substrate. For example, when the gate voltage is 15 V and the source-drain voltage is 1200 V, if the material of the semiconductor substrate is silicon, then it is preferable that T=100 nm, and if the material of the semiconductor substrate is silicon carbide, it is preferable that T=50 nm. As a result, the maximum electric field at the trench gate insulating film and in the vicinity thereof can be held to approximately 3 MV/cm.

When formula (12) is represented in an XY coordinate plane, the result is a straight line passing through X=T and with slope (k3/k2). The larger the value of (k3/k2), the broader the range of values of Y satisfying formula (12) can be made. That is, the larger (k3/k2), the larger the film thickness Y can be made within the range in which an excellent turn-on characteristic is assured, and a MOSFET with a higher maximum voltage can be obtained. While no limitations in particular are imposed, it is preferable that (k3/k2) be 1.8 or higher.

In the MOSFET disclosed in the present specification, it is preferable that the following formulas (1) and (2) be satisfied.

[Math. 2]

X+Y>50/\sqrt{2} (1)

(k3/k2)(X−100)+Y<0 (2)

Further, one or both of the following formulas (3) and (4) may be satisfied.

[Math. 3]

X+Y>100/\sqrt{2} (3)

(k3/k2)(X−50)+Y<0 (4)

In the above-described formula (11), when Tox is set to 50 nm, formula (1) is obtained, and when Tox is set to 100 nm, formula (3) is obtained. In the above-described formula (12), when T is set to 100 nm, formula (2) is obtained, and when T is set to 50 nm, formula (4) is obtained.

Further, in the MOSFET disclosed in the present specification, it is preferable that the following formula (5) be satisfied. The following formula (5) is a formula indicating, for the case of a planar gate-type MOSFET, the range of X and Y in which it is difficult to obtain a MOSFET with an excellent time-dependent dielectric breakdown characteristic. Because the MOSFET disclosed in the present specification is the trench gate type, even under conditions satisfying the following formula (5), a satisfactory maximum voltage can be secured. Hence in the MOSFET disclosed in the present specification, the gate insulating film can be designed to be thinner than in a planar gate-type MOSFET. If the film thickness X and film thickness Y are included in formula (5), a MOSFET with a turn-on characteristic superior to that of a planar gate-type MOSFET can be obtained,

[Math. 4]

X+Y<T_{OX} (5)

The present specification further discloses a method of designing a MOSFET. By appropriately selecting the materials and film thicknesses of the second insulating film and the third insulating film using the above-described formulas (11) and (12), a MOSFET can be designed having a high maximum voltage and a low turn-on resistance. Further, the above-described formula (5) may be used. When there is some variation in the film thicknesses of the second insulating film and the third insulating film, at least the film thickness at the trench side surfaces in the vicinity of corner portions at the lower end of the gate electrode may be made to satisfy the above-described formula (11) and other conditions.

The MOSFET of the present specification can easily be manufactured using a semiconductor device manufacturing method of the prior art. No limitations in particular are imposed, but it is preferable that the first insulating film be manufactured by a method in which, after using a CVD method or similar to fill the trench interior with an insulating film, etching is performed to remove excess insulating film. No limitations in particular are imposed, but it is preferable that the second insulating film and third insulating film be manufactured by a method in which a CVD method, thermal oxidation method or similar is used to form thin insulating film in the trench and on the insulating film surface.

### EXAMPLE 1

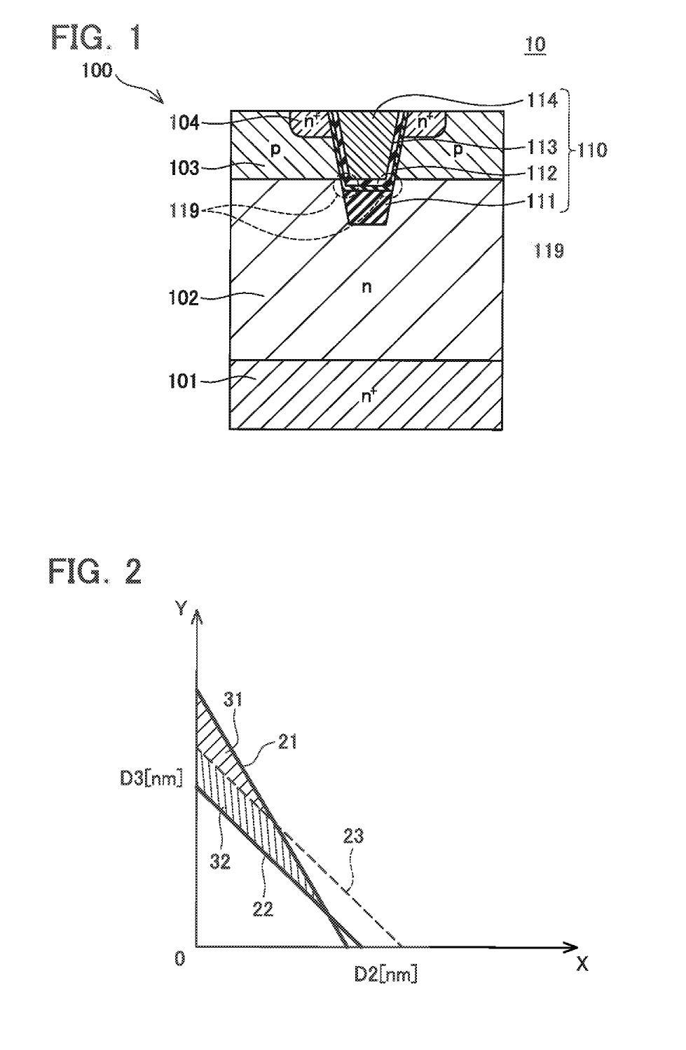

As shown in FIG. 1, a MOSFET 10 of Embodiment 1 comprises a semiconductor substrate 100 and a trench gate 110. Material of the semiconductor substrate 100 is silicon carbide. The semiconductor substrate 100 comprises an n⁺ type drain layer 101; n type drift layer 102 formed on a surface of the drain layer 101; p type body layer 103 formed on a surface of the drift layer 102; and n⁺ type source layer 104 formed on a part of a surface of the body layer 103. The drain layer 101 is exposed at a rear surface of the semiconductor substrate 100, and is in contact with a rear surface electrode (not shown). A part of the body layer 103 and the source layer 104 are exposed at a surface of the semiconductor substrate 100, and are in contact with a surface electrode (not shown). The trench gate 110 penetrates through the body layer 103 and the source layer 104 from the surface of the semiconductor substrate 100, and reaches the drift layer 102. The trench gate 110 comprises a first insulating film 111 provided on a bottom surface of the trench; second insulating film 112 provided on a trench side surface and on a surface of the first insulating film 111; third insulating film 113 provided on a surface of the second insulating film 112; and gate electrode 114 in contact with a surface of the third insulating film 113 and filling the trench interior. The second insulating film 112 is in contact with the surfaces of the first insulating film 111 and the body layer 103. The third insulating film 113 is provided in a state being in contact with both the gate electrode 114 and the second insulating film 112. The gate electrode 114 is isolated from the second insulating film 112 by the third insulating film 113, and is not in contact with the second insulating film 112. A bottom face of the gate electrode 114 extends to a position on a drift layer 102 side past an interface between the drift layer 102 and the body layer 103. Corner portions 119 of a lower end of the gate electrode 114 are isolated from the semiconductor substrate 100 by the second insulating film 112 and the third insulating film 113. The material of the second insulating film 112 is SiO₂, and the material of the third insulating film 113 is Si₃N₄.

FIG. 2 shows a relation between a film thickness X (X>0) of the second insulating film 112 and a film thickness Y (Y>0) of the third insulating film 113. A straight line indicated by the reference number 22 shows the film thickness X and film thickness Y satisfying the above-described formula (3); a straight line indicated by the reference number 21 shows the film thickness X and film thickness Y satisfying the above-described formula (4). A straight line (broken line) indicated by the reference number 23 shows the film thickness X and film thickness Y satisfying the above-described formula (5). Here, a dielectric constant of the second insulating film is k2=3.9, and a dielectric constant of the third insulating film is k3=7.

In FIG. 2, a range 31 indicates a range of the film thickness X and film thickness Y satisfying the conditions of the above-described formulas (3) to (5). A range 32 indicates a range of the film thickness X and film thickness Y satisfying the conditions of the above-described formulas (3) and (4), and not satisfying the condition of the above-described formula (5). A range 31 does not include the film thickness X and film thickness Y indicated by the straight line 21 and the straight line 23. Further, the range 32 does not include the film thickness X and film thickness Y indicated by the straight line 22, but does include the film thickness X and film thickness Y indicated by the straight line 23. In the MOSFET 10, the film thickness X and film thickness Y are set so as to be included in the range 32.

In the MOSFET 10 of this embodiment, the second insulating film 112 and third insulating film 113 are provided between the corner portions 119 of the lower end of the gate electrode 114 and the semiconductor substrate 100. Because the third insulating film 113 is formed of the material with the higher dielectric constant than the second insulating film 112, even if the film thickness Y is made thick in order to secure a high maximum voltage, an excellent turn-on characteristic can be maintained. Further, if the third insulating film 113 with the high dielectric constant is in contact with the semiconductor substrate 100, many carriers are captured at an interface state at the interface between the third insulating film 113 and the semiconductor substrate 100, and the speed of channel formation may become slow. In the MOSFET 10, the second insulating film 112 with the comparatively low dielectric constant is in contact with the body layer 103, so that slowing of the speed of channel formation can also be prevented. The film thickness X of the second insulating film 112 and the film thickness Y of the third insulating film 113 are set so as to be included in the range 32 satisfying the above-described formulas (3) to (5). Hence, the MOSFET 10 has excellent reliability with respect to time-dependent dielectric breakdown, and moreover has an excellent turn-on characteristic. As explained above, the MOSFET 10 of this embodiment has the high maximum voltage, and the excellent turn-on characteristic.

In the above, an embodiment of the present teaching has been explained in detail, but the embodiment is merely an exemplification, and does not limit the scope of the claims. The features disclosed in the scope of claims include various modifications and alterations of the specific example of the above exemplification.

The technical elements explained in the present specification or the drawings exhibit advantageous effects either singly or in various combinations, and are not limited to the combinations disclosed in the claims at the time of filing. Further, features exemplified in the present specification or in the drawings can attain a plurality of objects simultaneously, and attainment of a single object thereamong is itself an advantageous effect.

1. A vertical MOSFET comprising:
a semiconductor substrate comprising a first conductivity type drain layer, a first conductivity type drift layer formed on an upper surface of the drain layer, a second conductivity type body layer formed on an upper surface of the drift layer, and a first conductivity type source layer formed on a part of an upper surface of the body layer; and
a trench gate penetrating through the source layer and the body layer from an upper surface of the semiconductor substrate and reaching the drift layer;
wherein
the trench gate comprises:
a gate electrode;
a first insulating film disposed on a bottom surface of a trench formed in the semiconductor substrate and in contact with the drift laver;
a second insulating film disposed on a side surface of the trench and upper surface of the first insulating film, and in contact with the body layer; and
a third insulating film disposed between the gate electrode and the second insulating film, and formed of a material of which dielectric constant is higher than a dielectric constant of the second insulating film.

2. The MOSFET according to claim 1, wherein
a material of the second insulating film is silicon oxide, and
the dielectric constant of the material of the third insulating film is higher than a dielectric constant of silicon oxide.

3. The MOSFET according to claim 1, wherein
the MOSFET satisfies following formulas (1) and (2), where a dielectric constant of the second insulating film is k2, a thickness of the second insulating film is X nm, a dielectric constant of the third insulating film is k3, and a thickness of the third insulating film is Y nm:
[Math. 5]
X+Y>50/\sqrt{2} (1)
(k3/k2)(X−100)+Y<0 (2).

4. The MOSFET according to claim 3, wherein the MOSFET further satisfies a following formula (3):
[Math. 6]
X+Y>100/\sqrt{2} (3).

5. The MOSFET according to claim 3, wherein the MOSFET further satisfies a following formula (4):
[Math. 7]
(k3/k2)(X−50)+Y<0 (4).

6. The MOSFET according to claims 1-5, wherein the third insulating film is in contact with the gate electrode.
